(19) United States
(12) Patent Application Publication
(10) Pub. No.: US 2026/0158447 A1
(43) Pub. Date: Jun. 11, 2026

(54) Multilayer Coated Vent Assembly

(71) Applicant: W. L. Gore & Associates, Inc., Newark, DE (US)

(72) Inventors: Nicole Tavormina, Newark, DE (US); David DeGennaro, Newark, DE (US)

(73) Assignee: W. L. Gore & Associates, Inc., Newark, DE (US)

(21) Appl. No.: 19/291,811

(22) Filed: Aug. 6, 2025

Related U.S. Application Data
(60) Provisional application No. 63/680,137, filed on Aug. 7, 2024.

(51) Int. Cl. B01D 63/08; B01D 46/54; B01D 46/62; B01D 53/22; B01D 69/02; B01D 71/26; B01D 71/64; B01D 71/70; H04R 1/02; H04R 1/08; H05K 5/02

(52) U.S. Cl. CPC B01D 63/082; B01D 46/543; B01D 46/62; B01D 53/226; B01D 53/228; B01D 69/02; B01D 71/261; B01D 71/64; B01D 71/70; H04R 1/023; H04R 1/086; H05K 5/0214; H05K 5/0215; B01D 2053/222; B01D 2279/35; B01D 2279/45; B01D 2325/20; B01D 2325/38

(57) ABSTRACT

There is provided a vent assembly comprising a membrane stack, the membrane stack comprising a plurality of membranes and an air gap between adjacent membranes in the plurality of membranes, wherein each membrane in the plurality of membranes comprise a non-fluoropolymer and substantially occlude each other in the membrane stack, wherein a first membrane in the plurality of membranes has an isopropyl alcohol (IPA) rating of at least 30% IPA/water.

### FIELD

The present disclosure relates to vent assemblies for use with devices, especially to vent assemblies for use with electronic devices, and devices, especially electronic devices, comprising the same.

### BACKGROUND

Electronic devices that comprise acoustic transducers such as speakers and microphones often comprise vents or vent assemblies that protect such acoustic transducers from the contact with contaminants such as particulates or liquids. Such vents or vent assemblies typically occlude an aperture in the housing of the electronic device through which sound travels from or to the speaker or microphone respectively.

Alternative devices require pressure to be equilibrised between the interior of the device and its exterior whilst also preventing ingress of contaminants, while not being required to transmit sound.

The materials used to make up the vents or vent assemblies are required to be resistant to the passage of particulates and liquids, especially liquid water, whilst also in some applications maximising the transmission of sound through them.

Typically, in order to ensure that the interior of the electronic device is adequately protected from particulates and liquids, the membrane of the vent or vent assembly is tailored to prevent ingress of particulates and liquids and for certain applications trying to minimise the impact of the membrane on the ability of vent assembly to equilibrate the pressure across the vent or vent assembly. Further, such membranes are tailored to not degrade in their ability to vent pressure or resist ingress of water after exposure to chemical contamination (such as may happen if the device comes into contact with soapy water, e.g.).

However, the properties of new electronic devices are required to constantly be improving by the expectations of users whilst also ensuring that these electronic devices become more durable and resistant to damage due to ingress of liquids and particulates.

Furthermore, vents and vent assemblies often use fluoropolymer membranes which belong to a class of materials known as per- or poly-fluoroalkyl substances (PFAS). PFAS materials may provide superior performance, but may be subject to use restrictions that may preclude their use in such applications.

Accordingly, it is desirable to provide vents and vent assemblies that do not incorporate fluoropolymer membranes and that offer similar performance in ability to vent pressure, prevent ingress of water and contaminants, and retain such performance after exposure to chemical contamination.

The present disclosure is intended at least in part to address at least one of these issues.

### SUMMARY

According to a first embodiment, there is provided a vent assembly comprising a membrane stack, the membrane stack comprising a plurality of membranes and an air gap between adjacent membranes in the plurality of membranes, wherein each membrane in the plurality of membranes comprise a non-fluoropolymer and substantially occlude each other in the membrane stack, wherein a first membrane in the plurality of membranes has an isopropyl alcohol (IPA) rating of at least 30% IPA/water.

Typically, when the vent assembly is installed in the housing of a device, the first membrane corresponds to the part of the membrane stack that faces the exterior of the housing. Accordingly, any contaminant must first pass through the first membrane.

In other words, the first membrane is the first membrane in the membrane stack.

Each membrane in the plurality of membranes may be spaced apart from adjacent membranes in the plurality of membranes by an air gap. Accordingly, the surfaces a given membrane do not abut or contact one of adjacent membranes in the membrane stack under typical conditions.

The air gap between adjacent membranes may be at least 20 μm. Accordingly, the distance between adjacent surfaces of adjacent membranes in the membrane stack may be at least 20 μm. In the membrane stack, membrane layers may be separated by intervening layers of material, for example an adhesive, and regions of the membrane adjacent to the intervening layers of material may not be in contact with the intervening material. The air gap may be defined as the membrane separation distance at the edge of the intervening material, such that the thickness of the air gap is defined by the thickness of the of intervening material. The membrane separation distance at points away from the edge of the adhesive may vary, but may typically be of similar or near identical scale to the air gap.

The air gap between adjacent membranes may be at least 25 μm. The air gap between adjacent membranes may be at least 30 μm.

The air gap between adjacent membranes may be from 20 μm to 100 μm. The air gap between adjacent membranes may be from 25 μm to 100 μm. The air gap between adjacent membranes may be from 30 μm to 100 μm. The air gap between adjacent membranes may be from 20 μm to 90 μm. The air gap between adjacent membranes may be from 20 μm to 80 μm. The air gap between adjacent membranes may be from 20 μm to 70 μm. The air gap between adjacent membranes may be from 20 μm to 60 μm. The air gap between adjacent membranes may be from 20 μm to 50 μm.

The first membrane may comprise a coating. The coating may reduce the surface energy of at least an outward facing surface of the first membrane. Typically, the first membrane comprises a material and the coating may reduce the surface energy of the first membrane below the surface energy of the material. The coating may improve the ability of the first membrane to resist contamination. The coating may make the first membrane more oleophobic so that the first membrane has better resistance to oil-based contaminants.

The coating may cover at least a first surface of the first membrane. The coating may permeate into pores of the first membrane. The coating may substantially cover the material of the first membrane through out the microstructure of the first membrane.

The coating may comprise an acrylate copolymer, poly(methyl methacrylate) (PMMA), silicone or polysiloxane.

In some embodiments the first membrane may comprise a polysiloxane. For example, the first membrane may comprise a polysiloxane.

The first membrane may comprise an oleophobic non-fluoropolymer.

In embodiments where the first membrane comprises a non-fluoropolymer that is sufficiently hydrophobic, the first membrane may have an IPA rating of at least 30% without requiring a coating.

In embodiments where the first membrane comprises a coating, the non-fluoropolymer may be selected from the group: polyamide (PA), a co-polyamide, polyimide (PI), a co-polyimide, polyamide-imide (PAI), polyacrylic acid (PAA), polyamideamine-epichlorohydrin (PAE), polyethersulfone (PES), polybenzimidazole (PBI), polyacrylonitrile (PAN), poly(methyl methacrylate) (PMMA), polylactic acid (PLA), silk, chitosan, celluloseacetate, polyethylene teraphthalate (PET), polycaprolactone (PCL), polyhydroxyalkanoates (PHA), polyhydroxybutyrate (PHB), polypropylene (PP), or polyethylene (PE). The non-fluoropolymer may be selected from the group: polyethylene, polypropylene, polyimide, polyamide, or polyurethane. The non-fluoropolymer may be polyethylene or polyimide.

The non-fluoropolymer may be a fibrillated material. Accordingly, the non-fluoropolymer may have a microstructure comprising nodes interconnected by fibrils. The non-fluoropolymer may have a microstructure comprising predominantly fibrils. The coating may coat the microstructure of the non-fluoropolymer. The coating may coat the fibrils of the microstructure of the non-fluoropolymer.

The non-fluoropolymer may have a microstructure comprising fibers, bundles of fibers, and a plurality of membrane pores, where the fibers and bundles of fibers are interconnected, and the plurality of membrane pores are void spaces between the fibers and bundles of fibers.

The non-fluoropolymer may be an electrospun, melt-blown or rotary jet spun polymer membrane.

The first membrane may have an IPA rating of at least 35% IPA/water. The first membrane may have any IPA rating of from 30% to 100% IPA/water. The first membrane may have any IPA rating of from 35% to 100% IPA/water. The first membrane may have any IPA rating of from 30% to 90% IPA/water. The first membrane may have any IPA rating of from 30% to 80% IPA/water. The first membrane may have any IPA rating of from 30% to 70% IPA/water. The first membrane may have any IPA rating of from 30% to 60% IPA/water.

It will be understood that the IPA rating of a membrane or surface provided here is as measured using the test method provided below. Further, it will be appreciated that it would be desirable for the IPA rating of the first membrane to be as high as possible.

The thickness of each membrane in the plurality of membranes may be at least 5 μm. The thickness of each membrane in the plurality of membranes may be at least 7 μm. The thickness of each membrane in the plurality of membranes may be at least 10 μm. The thickness of each membrane in the plurality of membranes may be at least 15 μm.

The thickness of each membrane in the plurality of membranes may be from 5 μm to 200 μm. The thickness of each membrane in the plurality of membranes may be from 5 μm to 150 μm. The thickness of each membrane in the plurality of membranes may be from 5 μm to 100 μm. The thickness of each membrane in the plurality of membranes may be from 7 μm to 200 μm. The thickness of each membrane in the plurality of membranes may be from 7 μm to 150 μm. The thickness of each membrane in the plurality of membranes may be from 7 μm to 100 μm. The thickness of each membrane in the plurality of membranes may be from 10 μm to 200 μm. The thickness of each membrane in the plurality of membranes may be from 10 μm to 150 μm. The thickness of each membrane in the plurality of membranes may be from 10 μm to 100 μm. The thickness of each membrane in the plurality of membranes may be from 15 μm to 200 μm. The thickness of each membrane in the plurality of membranes may be from 15 μm to 150 μm. The thickness of each membrane in the plurality of membranes may be from 15 μm to 100 μm.

The thickness of each membrane in the plurality of membranes may be from 5 μm to 90 μm. The thickness of each membrane in the plurality of membranes may be from 5 μm to 80 μm. The thickness of each membrane in the plurality of membranes may be from 5 μm to 70 μm. The thickness of each membrane in the plurality of membranes may be from 5 μm to 60 μm. The thickness of each membrane in the plurality of membranes may be from 5 μm to 50 μm.

The plurality of membranes may comprise two membranes or more. The plurality of membranes may comprise three membranes or more. The plurality of membranes may comprise four membranes or more.

In some embodiments, the plurality of membranes comprises a first membrane, a second membrane and a third membrane. The second membrane may be positioned between the first membrane and the third membrane. The membrane stack may comprise a first air gap positioned between the first membrane and the second membrane, and a second air gap positioned between the second membrane and the third membrane.

The first membrane may have a first surface adjacent to the first air gap and a second surface opposed to the first surface and at least the second surface has an IPA rating of at least 30% IPA/water. Both the first surface and the second surface may have an IPA rating of at least 30% IPA/water.

The first membrane may comprise polyethylene or polyimide.

The second membrane may comprise polyethylene or polyimide.

The third membrane may comprise polyethylene.

In some embodiments, the first membrane comprises polyethylene or polyimide, the second membrane comprises polyethylene or polyimide and the third membrane comprises polyethylene.

In some embodiments, the first membrane comprises polyethylene or polyimide and comprises a coating, the second membrane comprises polyethylene or polyimide and the third membrane comprises polyethylene.

The second membrane may have an IPA rating of at least 30% IPA/water. The second membrane may have an IPA rating of at least 35% IPA/water. The second membrane may have any IPA rating of from 30% to 100% IPA/water. The second membrane may have any IPA rating of from 35% to 100% IPA/water. The second membrane may have any IPA rating of from 30% to 90% IPA/water. The second membrane may have any IPA rating of from 30% to 80% IPA/water. The second membrane may have any IPA rating of from 30% to 70% IPA/water. The second membrane may have any IPA rating of from 30% to 60% IPA/water.

In embodiments where the plurality of membranes comprises at least three membranes, the second membrane may have an IPA rating of at least 30% IPA/water.

The second membrane may comprise a coating. For example, the coating may comprise silicone or polysiloxane. Typically, the coating of the second membrane is as described for the coating of the first membrane. It will be understood that the coating of the second membrane may be different to the coating of the first membrane in a specific embodiment or it may be the same.

The third membrane may not comprise a coating.

The vent assembly may have a failure pressure of at least 2 psi as measured in a water entry pressure (WEP) test using the test methods provided herein. The vent assembly may have a failure pressure of at least 5 psi as measured in a WEP test using the test methods provided herein. The vent assembly may have a failure pressure of at least 10 psi as measured in a WEP test using the test methods provided herein. The vent assembly may have a failure pressure of at least 20 psi as measured in a WEP test using the test methods provided herein. The vent assembly may have a failure pressure of at least 30 psi as measured in a WEP test using the test methods provided herein. The vent assembly may have a failure pressure of at least 40 psi as measured in a WEP test using the test methods provided herein. The vent assembly may have a failure pressure of at least 50 psi as measured in a WEP test using the test methods provided herein. The vent assembly may have a failure pressure of at least 60 psi as measured in a WEP test using the test methods provided herein.

The vent assembly may have a failure pressure of at least 70 psi as measured in a WEP test using the test methods provided herein. The vent assembly may have a failure pressure of at least 80 psi as measured in a WEP test using the test methods provided herein. The vent assembly may have a failure pressure of at least 90 psi as measured in a WEP test using the test methods provided herein. The vent assembly may have a failure pressure that is higher than can be measured using the test methods provided herein.

The vent assembly may have a failure pressure of from 2 psi to 90 psi as measured in a WEP test using the test methods provided herein. The vent assembly may have a failure pressure of from 5 psi to 90 psi as measured in a WEP test using the test methods provided herein. The vent assembly may have a failure pressure of from 10 psi to 90 psi as measured in a WEP test using the test methods provided herein. The vent assembly may have a failure pressure of from 20 psi to 90 psi as measured in a WEP test using the test methods provided herein. The vent assembly may have a failure pressure of from 30 psi to 90 psi as measured in a WEP test using the test methods provided herein. The vent assembly may have a failure pressure of from 40 psi to 90 psi as measured in a WEP test using the test methods provided herein. The vent assembly may have a failure pressure of from 50 psi to 90 psi as measured in a WEP test using the test methods provided herein. The vent assembly may have a failure pressure of from 60 psi to 90 psi as measured in a WEP test using the test methods provided herein.

In some embodiments the vent assembly may have a failure pressure of from 70 psi to 90 psi as measured in a WEP test using the test methods provided herein. The vent assembly may have a failure pressure of from 80 psi to 90 psi as measured in a WEP test using the test methods provided herein. The vent assembly may have a failure pressure of from 70 psi to 90 psi as measured in a WEP test using the test methods provided herein.

The vent assembly may have a water entry pressure (WEP) after a surfactant challenge of at least 10 psi using the test method described herein. The vent assembly may have a water entry pressure after a surfactant challenge of at least 15 psi using the test method described herein. The vent assembly may have a water entry pressure after a surfactant challenge of at least 20 psi using the test method described herein.

The vent assembly may have a water entry pressure after a surfactant challenge of from 10 psi to 90 psi using the test method described herein. The vent assembly may have a water entry pressure after a surfactant challenge of from 15 psi to 90 psi using the test method described herein. The vent assembly may have a water entry pressure after a surfactant challenge of from 20 psi to 90 psi using the test method described herein.

The vent assembly may have a reduction of airflow of less than 80% after a contamination test as measured using the test method described herein. The vent assembly may have a reduction of airflow of less than 75% after a contamination test as measured using the test method described herein. For the avoidance on doubt, the reduction of airflow through the vent assembly is calculated as:

$$Δ Airflow = ( - ( {a}_{i} - {a}_{p} ) / {a}_{i} ) \times 100$$

where aₚ is the airflow after the challenge and aᵢ is the airflow before the challenge.

The membrane stack may comprise an adhesive layer between at least the first membrane and the second membrane in the membrane stack. The membrane stack may comprise an adhesive layer between adjacent membranes in the membrane stack. The membrane stack may comprise an adhesive layer between each pair of adjacent membranes in the membrane stack.

The or each adhesive layer may define an adhesive layer aperture and each membrane in the plurality of membranes may occlude the adhesive layer aperture.

In embodiments where the membrane stack comprises a first membrane, a second membrane and a third membrane, the membrane stack may comprise a first adhesive layer between the first membrane and the second membrane and a second adhesive layer between the second membrane and the third membrane.

The adhesive of the or each adhesive layer may comprise a heat activated film (HAF). The adhesive of the or each adhesive layer may comprise a pressure sensitive adhesive (PSA). The adhesive of the or each adhesive layer may comprise an ultraviolet curable adhesive.

The adhesive layer may comprise an acrylic adhesive, or a silicone adhesive.

At least one membrane of the plurality of membranes may have a bubble point of at least 2 bar (29 psi) as measured using the test method provided herein. In embodiments comprising a first membrane, a second membrane and a third membrane, at least one of the first membrane, the second membrane and the third membrane may have a bubble point of at least 2 bar as measured using the test method provided herein. For example, the third membrane may have a bubble point of at least 2 bar.

At least one membrane of the plurality of membranes may have a bubble point of at least 2.5 bar. At least one membrane of the plurality of membranes may have a bubble point of at least 3 bar. At least one membrane of the plurality of membranes may have a bubble point of at least 3.5 bar. At least one membrane of the plurality of membranes may have a bubble point of at least 4 bar.

At least one membrane of the plurality of membranes may have a bubble point of from 2 bar to 15 bar. At least one membrane of the plurality of membranes may have a bubble point of from 2.5 bar to 15 bar. At least one membrane of the plurality of membranes may have a bubble point of from 3 bar to 15 bar. At least one membrane of the plurality of membranes may have a bubble point of from 3.5 bar to 15 bar. At least one membrane of the plurality of membranes may have a bubble point of from 4 bar to 15 bar. At least one membrane of the plurality of membranes may have a bubble point of from 5 bar to 15 bar. At least one membrane of the plurality of membranes may have a bubble point of from 6 bar to 15 bar. At least one membrane of the plurality of membranes may have a bubble point of from 2 bar to 14 bar. At least one membrane of the plurality of membranes may have a bubble point of from 2 bar to 13 bar. At least one membrane of the plurality of membranes may have a bubble point of from 2 bar to 12 bar. At least one membrane of the plurality of membranes may have a bubble point of from 2 bar to 11 bar.

For example, in some embodiments, at least one membrane of the plurality of membranes may have a bubble point of from 6 bar to 11 bar. At least one membrane of the plurality of membranes may have a bubble point of from 5 bar to 12 bar.

The plurality of membranes may comprise a final membrane. The final membrane may be on the side of the membrane stack opposed to the first membrane. For example, in embodiments comprising three membranes, the final membrane is the third membrane.

The final membrane may have a bubble point of at least 2 bar. The final membrane may have a bubble point of at least 2.5 bar. The final membrane may have a bubble point of at least 3 bar. The final membrane may have a bubble point of at least 3.5 bar. The final membrane may have a bubble point of at least 4 bar.

The final membrane of the plurality of membranes may have a bubble point of from 2 bar to 15 bar. The final membrane of the plurality of membranes may have a bubble point of from 2.5 bar to 15 bar. The final membrane of the plurality of membranes may have a bubble point of from 3 bar to 15 bar. The final membrane of the plurality of membranes may have a bubble point of from 3.5 bar to 15 bar. The final membrane of the plurality of membranes may have a bubble point of from 4 bar to 15 bar. The final membrane of the plurality of membranes may have a bubble point of from 5 bar to 15 bar. The final membrane of the plurality of membranes may have a bubble point of from 6 bar to 15 bar. The final membrane of the plurality of membranes may have a bubble point of from 2 bar to 14 bar. The final membrane of the plurality of membranes may have a bubble point of from 2 bar to 13 bar. The final membrane of the plurality of membranes may have a bubble point of from 2 bar to 12 bar. The final membrane of the plurality of membranes may have a bubble point of from 2 bar to 11 bar.

In a second aspect there is provided a device comprising a housing defining an aperture and a vent assembly according to the first aspect positioned over the aperture, the housing having an interior and an exterior, wherein the first membrane of the membrane stack of the vent assembly faces the exterior of the housing.

Accordingly, contaminants entering the aperture must past through the first membrane first before passing through the remainder of the membranes of the membrane stack. Therefore, in order for a contaminant to enter the interior of the housing it must pass through all of the membranes of the membrane stack.

The device may be an electronic device.

The vent assembly may be positioned adjacent to an acoustic transducer. The acoustic transducer may be a speaker or a microphone. The acoustic transducer may be positioned adjacent to the vent assembly such that any contaminant must pass through the vent assembly before contacting the acoustic transducer.

### BRIEF DESCRIPTION OF THE FIGURES

Embodiments of the present invention will now be described, by way of non-limiting example, with reference to the accompanying drawings.

FIG. 1: A schematic side cross-sectional view of a vent assembly according to an embodiment;

FIG. 2: A schematic side cross-sectional view of a device according to an embodiment comprising the vent assembly of FIG. 1;

FIG. 3: A schematic side cross-sectional view of a vent assembly according to an embodiment;

FIG. 4: A schematic side cross-sectional view of an electronic device according to an embodiment comprising the vent assembly of FIG. 3;

FIG. 5: A schematic side cross-sectional view of a vent assembly according to an embodiment;

FIG. 6: A schematic side cross-sectional view of an electronic device according to an embodiment comprising the vent assembly of FIG. 5;

FIG. 7: A schematic side cross-sectional view of a vent assembly according to an embodiment;

FIG. 8: A schematic side cross-sectional view of an electronic device according to an embodiment comprising the vent assembly of FIG. 7;

FIG. 9: A schematic side cross-sectional view of a vent assembly according to an embodiment; and

FIG. 10: A schematic side cross-sectional view of an electronic device according to an embodiment comprising the vent assembly of FIG. 9.

### DETAILED DESCRIPTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

### Test Methods

### Vent Assembly Construction

Each test sample part was constructed on a 0.3 mm thick FR4 (glass reinforced epoxy) coupon having an 8 mm diameter hole in the center. A layer of acrylic adhesive (Part number 4983 from Tesa SE) is adhered on top of the FR4 coupon, having a 8 mm hole aligned with the hole in the FR4 coupon. The first layer of membrane, held flat and taught, is adhered to this first layer of adhesive. This first layer of membrane on the 8 mm diameter FR4 coupon is the facing the challenge.

If the desired part comprises a single layer of membrane, a second layer of acrylic adhesive (Part number 4983 from Tesa SE) with a 1.5 mm hole aligned with the other holes in the stack is adhered to the membrane, and a 0.3 mm thick FR4 coupon with a 1.5 mm hole aligned with the other holes in the stack is adhered to the top of that second layer of adhesive. This yields a single layer of membrane with a circular exposed region with an outer diameter of 1.5 mm, suspended between layers of acrylic adhesive, restrained between two coupons of FR4.

If the desired part comprises more than one layer of membrane, additional layers of membrane and adhesive (Part number 5603R from Nitto Denko Corporation) with 1.5 mm holes aligned with the other holes in the stack were added prior to rolling and bonding. This yields multiple layers of membrane with circular exposed regions with outer diameters of 1.5 mm, aligned and suspended between layers of acrylic adhesive, restrained between two coupons of FR4, with air gaps defined by the thickness of the acrylic adhesive (Part number 5603R from Nitto Denko Corporation).

In all constructions, the first membrane layer is adjacent to the FR4 coupon having an opening of 8 mm, and this is the side of the part stack that is challenged directly in test methods described herein.

Such part constructions were used in tests for water entry pressure and air flow measurements before and after exposure to surfactant water as described below.

### Water Entry Pressure (WEP) Test

### Initial Test

The water entry pressure (WEP) test is applied to a vent assembly and the vent assembly is clamped and sealed in a sample holder. Water pressure is applied to one side (having the first membrane) and the pressure was ramped up in small increments (0.03 psi/s) from 0-90 psi over a period of 50 minutes. If water does not intrude through the vent assembly to be visible on the opposite side during the specified duration, the sample is deemed to have passed the WEP test. After the test duration, the sample can be disassembled and it can be determined whether water has passed through each membrane or none of the above.

### Post Contamination

Samples are immersed at a depth of 10 cm in a 0.1% solution of a surfactant composition by weight in deionized water for a period of 10 minutes. The surfactant composition comprises 7-13% total anionic surfactant (sodium laureth sulfate and sodium lauryl sulfate) and 1-5% alkyl dimethyl amine oxide and was sourced from The Proctor & Gamble Company under the product name “Ivory Liquid Hand Dishwashing Detergents Product-Ultra Ivory Classic Scent”. This process is repeated for 3 cycles and then the samples are dried in an oven at 50° C. for 1 hour.

The WEP for the samples was then measured using the procedure described above.

### Airflow Measurement (for Membranes)

The airflow test measures laminar volumetric flow rates of air through membrane samples. Each membrane sample was clamped between two plates in a manner that seals an area of 2.99 cm² across the flow pathway. An ATEQ® (ATEQ Corp., Livonia, MI) Premier D Compact Flow Tester was used to measure airflow rate (L/hr) through each membrane sample by challenging it with a differential air pressure of 1.2 kPa (12 mbar) through the membrane.

### Airflow Measurement (for Vent Assemblies)

### Initial

This defines a test method for measuring laminar volumetric flow rates of air through vent assembly samples. The sample assembly is clamped between two plates in a manner that only compression to the FR4 coupons and seals against the surfaces with an O-ring. An ATEQ Premier D Compact Flow Tester is used to measure airflow rate (mL/min) through the vent assembly by challenging it with 7 kPa of air pressure through the orifice in the steel plate.

### Post Contamination

Samples are immersed at a depth of 10 cm in a 0.1% solution of a surfactant composition by weight in deionized water for a period of 10 minutes. The surfactant composition comprises 7-13% total anionic surfactant (sodium laureth sulfate and sodium lauryl sulfate) and 1-5% alkyl dimethyl amine oxide and was sourced from The Proctor & Gamble Company under the product name “Ivory Liquid Hand Dishwashing Detergents Product—Ultra Ivory Classic Scent”. This process is repeated for 3 cycles and then the samples are dried in an oven at 50° C. for 1 hour.

The airflow for the samples was then measured using the procedure described above.

### Mass Per Area

Samples were die cut to form circular sections of 5.64 cm radius (area=100 cm²). Each sample was weighed using a Mettler Toledo ME104TE Analytical balance and the average of six samples was divided by the test area of 100 cm² and multiplied by 100 to calculate the mass per area in units of g/m².

### Non-Contact Thickness

The non-contact thickness of the membranes was measured using a KEYENCE LS-7600 laser system (commercially available from KEYENCE America). The optical measurement is made by gently placing the sample membrane against a polished stainless cylinder having a 2.54 cm diameter and smoothing it down with minimal applied tension. The thickness of the sample is determined by measurement of the shadow created in the parallel light path of within the two ends of the Keyence laser micrometer. The average of the three measurements was utilized to provide a mean non-contact thickness.

### Bubble Point Test

The bubble point was measured according to the general teachings of ASTM F316-03 using a Capillary Flow Porometer (Model 3 Gzh from Quantachrome Instruments). The sample holder comprised a porous metal plate (Part Number: 196450, Anton Paar), 25.4 mm in diameter and a plastic mask (Part Number ABF-300, Professional Plastics), 18 mm inner diameter×24.5 mm outer diameter. The sample was placed in between the metal plate and the plastic mask. The sample was then clamped down and sealed using an O-ring (Part Number: 193798, Anton Paar). The sample was wet with the test fluid (Silicone fluid, 10 cSt, having a surface tension of 19.75 dynes/cm). The porous metal plate was covered with 2-3 mm of the test fluid and the pressure of gas (filtered air) applied to the side of the sample opposed to the test fluid was increased slowly. The lowest pressure at which a steady stream of bubbles rise from the central area of the test fluid is recorded as the bubble point.

### IPA Rating Test

The resistance to wetting or the degree of contamination resistance is measured using an isopropyl alcohol (IPA) wetting rating test. In this test drops of solution of different ratios of IPA to water (starting at 0% and increasing in 5% intervals) are placed on the substrate and viewed for about 30 seconds for wetting as indicated by clarification of the substrate. Fully wet-out areas become translucent to transparent. This indicates that the test fluid has entered sample pores. Samples that retain the original opacity have not wet-out. A higher percent IPA solution indicates a higher degree of contamination resistance. Accordingly, an IPA rating of 30% corresponds to a material that does not wet fully with an IPA solution having 30% IPA but did wet at a higher IPA %, such as 35%, for example.

### GENERAL EXAMPLES

### Example 1

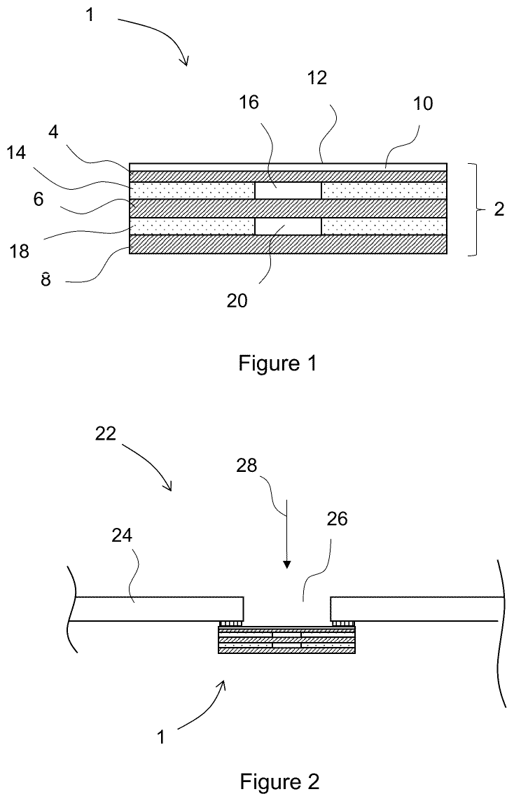

With reference to FIGS. 1 and 2, there is a provided a vent assembly 1 comprising a membrane stack 2. The membrane stack 2 comprises a first membrane 4, a second membrane 6 and a third membrane 8. The first membrane 4, the second membrane 6 and the third membrane 8 completely overlap and occlude one another. The first membrane 4 comprises an expanded polyethylene (ePE) membrane with a silicone coating 10 provided on a first side 12 of the first membrane 4. The second membrane 6 comprises an ePE membrane. The third membrane 8 comprises an ePE membrane.

A first adhesive layer 14 comprising a heat activated film (HAF) is provided between the first membrane 4 and the second membrane 6 that adheres the first membrane 4 to the second membrane 6. The first adhesive layer 14 defines a first aperture 16 (acting as a first air gap) and the first membrane 4 and the second membrane 6 occlude the first aperture 16. The first aperture 16 separates the first membrane 4 from the second membrane 6 by 30 μm.

A second adhesive layer 18 comprising a heat activated film (HAF) is provided between the second membrane 6 and the third membrane 8 that adheres the second membrane 6 to the third membrane 8. The second adhesive layer 18 defines a second aperture 20 (acting as a second air gap) and the second membrane 6 and the third membrane 8 occlude the second aperture 20. The second aperture 20 separates the second membrane 6 from the third membrane 8 by 30 μm.

FIG. 2 shows the vent assembly 1 installed in a device 22. The device 22 comprises a device housing 24 and the device housing 24 defines an aperture 26. The vent assembly 1 is adhered to the device housing 24 around the aperture 26 and fully occludes the aperture 26. The vent assembly 1 is oriented such that the first membrane 4 directly faces the aperture 26 with the side 12 of the first membrane 4 comprising the coating 10 directly adjacent to the aperture 26. Accordingly, any contaminant such as particulates or liquids must initially pass through the coated side 12 of the first membrane 4 in order to pass through the vent assembly 1 and then into the interior of the device housing 24 (see arrow 28 showing direction of contaminant challenge).

### Example 2

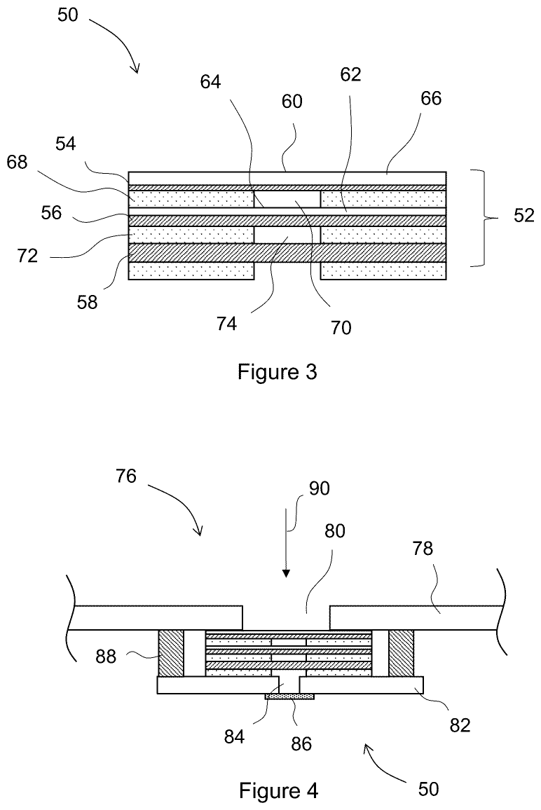

With reference to FIGS. 3 and 4, there is a provided a vent assembly 50 comprising a membrane stack 52. The membrane stack 52 comprises a first membrane 54, a second membrane 56 and a third membrane 58. The first membrane 54, the second membrane 56 and the third membrane 58 completely overlap and occlude one another. The first membrane 54 comprises an electrospun polyimide (PI) membrane with a silicone coating 66 provided on a first side 60 of the first membrane 54. The second membrane 56 comprises an ePE membrane and a silicone coating 62 is provided on a first side 64 of the second membrane 56. The third membrane 58 comprises an ePE membrane.

A first adhesive layer 68 comprising a heat activated film (HAF) is provided between the first membrane 54 and the second membrane 56 that adheres the first membrane 54 to the second membrane 56. The first adhesive layer 68 defines a first aperture 70 (acting as a first air gap) and the first membrane 54 and the second membrane 56 occlude the first aperture 70. The first aperture 70 separates the first membrane 54 from the second membrane 56 by 25 μm.

A second adhesive layer 72 comprising a heat activated film (HAF) is provided between the second membrane 56 and the third membrane 58 that adheres the second membrane 56 to the third membrane 58. The second adhesive layer 72 defines a second aperture 74 (acting as a second air gap) and the second membrane 56 and the third membrane 58 occlude the second aperture 74. The second aperture 74 separates the second membrane 56 from the third membrane 58 by 25 μm.

FIG. 4 shows the vent assembly 50 installed in an electronic device 76. The electronic device 76 comprises a housing 78 and the housing 78 defines an aperture 80. The vent assembly 50 is adhered to a substrate 82 and the first membrane 54 directly abuts the housing 78 around the aperture 80 and fully occludes the aperture 80. The substrate 82 defines an acoustic aperture 84 and a speaker 86 is provided directly beneath the acoustic aperture 84. A containment wall 88 is provided between the substrate 82 and the housing 78 to contain the vent assembly 50 therein. The vent assembly 50 is oriented such that the first membrane 54 directly faces the aperture 80 with the side 60 of the first membrane 54 comprising the coating 62 directly adjacent to the aperture 80. Accordingly, any contaminant such as particulates or liquids must initially pass through the coated side 60 of the first membrane 54 in order to pass through the vent assembly 50 and then into the interior of the housing 78 (see arrow 90 showing direction of contaminant challenge).

### Example 3

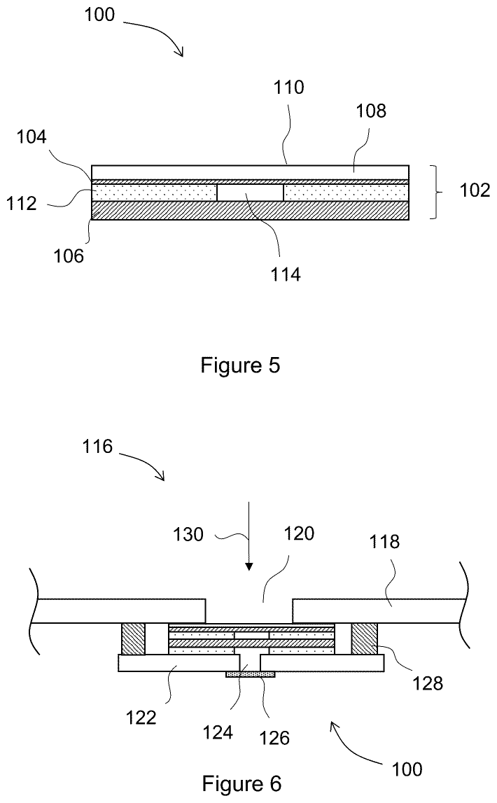

With reference to FIGS. 5 and 6, there is a provided a vent assembly 100 comprising a membrane stack 102. The membrane stack 102 comprises a first membrane 104, and a second membrane 106. The first membrane 104 and the second membrane 106 completely overlap and occlude one another. The first membrane 104 comprises an ePE membrane with a silicone coating 108 covering substantially all of the material of the microstructure of the first membrane 104. The second membrane 106 comprises an ePE membrane.

An adhesive layer 112 comprising a pressure sensitive adhesive (PSA) is provided between the first membrane 104 and the second membrane 106 that adheres the first membrane 104 to the second membrane 106. The adhesive layer 112 defines an aperture 114 (acting as an air gap) and the first membrane 104 and the second membrane 106 occlude the aperture 114. The aperture 114 separates the first membrane 104 from the second membrane 106 by 35 μm.

FIG. 6 shows the vent assembly 100 installed in an electronic device 116. The electronic device 116 comprises a housing 118 and the housing 118 defines an aperture 120. The vent assembly 100 is adhered to a substrate 122 and the first membrane 104 directly abuts the housing 118 around the aperture 120 and fully occludes the aperture 120. The substrate 122 defines an acoustic aperture 124 and a microphone 126 is provided directly beneath the acoustic aperture 124. A containment wall 128 is provided between the substrate 122 and the housing 118 to contain the vent assembly 100 therein. The vent assembly 100 is oriented such that the first membrane 104 directly faces the aperture 120 with the side 110 of the first membrane 104 comprising the coating 108 directly adjacent to the aperture 120. Accordingly, and contaminant such as particulates or liquids must initially pass through the coated side 110 of the first membrane 104 in order to pass through the vent assembly 100 and then into the interior of the housing 118 (see arrow 130 showing direction of contaminant challenge).

### Example 4

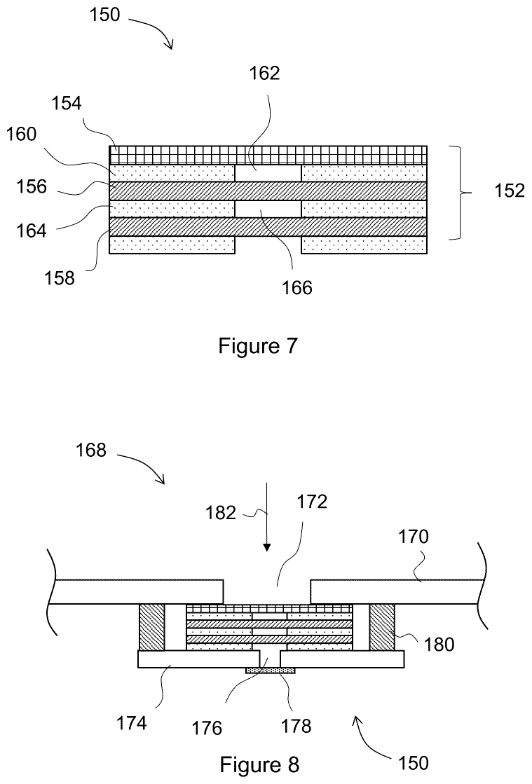

With reference to FIGS. 7 and 8, there is a provided a vent assembly 150 comprising a membrane stack 152. The membrane stack 152 comprises a first membrane 154, a second membrane 156 and a third membrane 158. The first membrane 154, the second membrane 156 and the third membrane 158 completely overlap and occlude one another. The first membrane 154 comprises a polysiloxane membrane. The second membrane 156 comprises an ePE membrane. The third membrane 158 comprises an ePE membrane.

A first adhesive layer 160 comprising a heat activated film (HAF) is provided between the first membrane 154 and the second membrane 156 that adheres the first membrane 154 to the second membrane 156. The first adhesive layer 160 defines a first aperture 162 (acting as a first air gap) and the first membrane 154 and the second membrane 156 occlude the first aperture 162. The first aperture 162 separates the first membrane 154 from the second membrane 156 by 30 μm.

A second adhesive layer 164 comprising a heat activated film (HAF) is provided between the second membrane 156 and the third membrane 158 that adheres the second membrane 156 to the third membrane 158. The second adhesive layer 164 defines a second aperture 166 (acting as a second air gap) and the second membrane 156 and the third membrane 158 occlude the second aperture 166. The second aperture 166 separates the second membrane 156 from the third membrane 158 by 30 μm.

FIG. 8 shows the vent assembly 150 installed in an electronic device 168. The electronic device 168 comprises a device housing 170 and the device housing 170 defines an aperture 172. The vent assembly 150 is adhered to a substrate 174 and the first membrane 154 directly abuts the device housing 170 around the aperture 172 and fully occludes the aperture 172. The substrate 174 defines an acoustic aperture 176 and a microphone 178 is provided directly beneath the acoustic aperture 176. A containment wall 180 is provided between the substrate 174 and the device housing 170 to contain the vent assembly 150 therein. The vent assembly 150 is oriented such that the first membrane 154 directly faces the aperture 172 and is directly adjacent to the aperture 172. Accordingly, any contaminant such as particulates or liquids must initially pass through the first membrane 154 in order to pass through the vent assembly 150 and then into the interior of the device housing 170 (see arrow 182 showing direction of contaminant challenge).

### Example 5

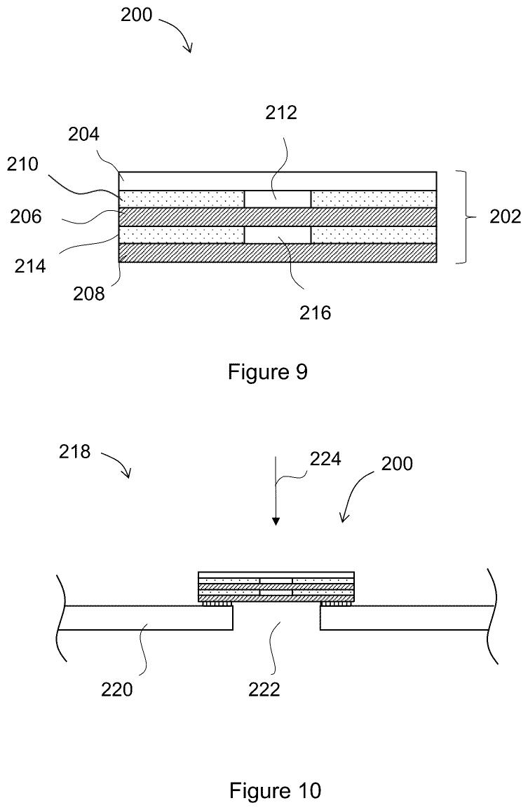

With reference to FIGS. 9 and 10, there is a provided a vent assembly 200 comprising a membrane stack 202. The membrane stack 202 comprises a first membrane 204, a second membrane 206 and a third membrane 208. The first membrane 204, the second membrane 206 and the third membrane 208 completely overlap and occlude one another. The first membrane 204 comprises an expanded polyethylene (ePE) membrane with a silicone coating provided through the material of the first membrane 204. The second membrane 206 comprises an ePE membrane. The third membrane 208 comprises an ePE membrane.

A first adhesive layer 210 comprising a heat activated film (HAF) is provided between the first membrane 204 and the second membrane 206 that adheres the first membrane 204 to the second membrane 206. The first adhesive layer 210 defines a first aperture 212 (acting as a first air gap) and the first membrane 204 and the second membrane 206 occlude the first aperture 212. The first aperture 212 separates the first membrane 204 from the second membrane 206 by 30 μm.

A second adhesive layer 214 comprising a heat activated film (HAF) is provided between the second membrane 206 and the third membrane 208 that adheres the second membrane 206 to the third membrane 208. The second adhesive layer 214 defines a second aperture 216 (acting as a second air gap) and the second membrane 206 and the third membrane 208 occlude the second aperture 216. The second aperture 216 separates the second membrane 206 from the third membrane 208 by 30 μm.

FIG. 10 shows the vent assembly 200 installed in a device 218. The device 218 comprises a device housing 220 and the device housing 220 defines an aperture 222. The vent assembly 200 is adhered to outside of the device housing 220 around the aperture 222 and fully occludes the aperture 222. The vent assembly 200 is oriented such that the third membrane 208 directly faces the aperture 222 with the third membrane 208 directly adjacent to the aperture 222. Accordingly, any contaminant such as particulates or liquids must initially pass through the first membrane 204 in order to pass through the vent assembly 200 and then into the interior of the device housing 220 (see arrow 224 showing direction of contaminant challenge).

### Specific Examples

### Materials

Expanded Polyethylene (ePE1)

A starting UHMW polyethylene resin having a weighted average molecular weight of 2.41×10⁶ g/mol, was used in gel method to manufacture a precursor film as a tape in accordance with the method disclosed in U.S. Pat. No. 8,465,565 to provide a gel-processed UHMWPE membrane.

The resulting gel-processed UHMWPE membrane had a mass/area of 7.1 g/m², a bubble point of 64.8 psi (4.5 bar), a measured ATEQ airflow of 6.1 L/hr at 12 mbar and 2.99 cm², a non-contact thickness of 62.1 μm.

Expanded Polyethylene (ePE2)

A starting UHMW polyethylene resin having a weighted average molecular weight of 2.6×10⁶ g/mol, was used in gel method to manufacture a precursor film as a tape in accordance with the method disclosed in U.S. Pat. No. 8,645,565 to provide a gel-processed UHMWPE membrane.

The resulting gel-processed UHMWPE membrane had a mass/area of 6.4 g/m², a bubble point of 97.5 psi (6.72 bar), a measured ATEQ airflow of 2.8 L/hr at 12 mbar and 2.99 cm², a non-contact thickness of 33.9 μm.

Expanded Polyethylene (ePE3)

One method known in the art to produce porous polyethylene membranes is through a wet or gel process. In this process, polyethylene is mixed with a hydrocarbon liquid and other additives. This mixture is heated over the polymer melt and extruded into a sheet. This sheet can then be orientated biaxially before and/or after the hydrocarbon liquid is extracted, producing a microporous membrane. Various process details are known, such as those disclosed in U.S. Pat. Nos. 5,248,461; 4,873,034; 5,051,183; and 6,566,012; each of which are hereby incorporated-by-reference in their entirety. Additional discussion includes Casting and stretching of filled and unfilled UHMW-polyethylene films, Ir.F.H. Assinck, Centre for polymers and composites, Eindhoven University of Technology, November 1995 and Porous Biaxially, drawn UHMWPE Films, H.M. Fortuin, DSM Research BV, Department of Materials Technology—Fifth Int. Conf. of Environmental Ergonomics.
1. The polyethylene membrane is formed from a polyethylene polymer comprising ultrahigh molecular weight polyethylene. As discussed above, in the context of the present disclosure, ultrahigh molecular weight polyethylene refers to polyethylene having an average molecular weight of about 1,000,000 g/mol to about 10,000,000 g/mol. In some embodiments, the ultrahigh molecular weight polyethylene polymer has an average molecular weight of about 1,500,000 to about 10,000,000 g/mol, or about 2,000,000 g/mol to about 10,000,000 g/mol, or about 4,000,000 g/mol to about 8,000,000 g/mol.
2. The ultrahigh molecular weight polyethylene polymer may be a homopolymer of ethylene or a copolymer of ethylene and at least one comonomer. Suitable copolymers include an alpha-olefin or a cyclic olefin having 3 to 20 carbon atoms, such as 1-butene, 1-pentene, 1-hexene, 1-heptene, 1-octene, cyclohexene, and dienes with up to 20 carbon atoms. The comonomer may be present in the polyethylene copolymer in an amount of from 0.001 mol % to 10 mol %, or from 0.01 mol % to 5 mol %, or from 0.1 mol % to 1 mol %.
3. The polyethylene polymer may also comprise a blend of ultrahigh molecular weight polyethylene and polyethylene having a relatively lower molecular weight, such as polyethylene having an average molecular weight of below about 1,000,000 g/mol.

The resulting polyethylene membrane, had a mass/area of 3.7 g/m², a bubble point of 157.9 psi (10.89 bar), a measured ATEQ airflow of 2.6 L/hr at 12 mbar and 2.99 cm², a non-contact thickness of 11.5 μm.

### Polyimide Membrane (PI1)

A polyimide electrospun membrane available from W.L. Gore & Associates with the part number GCM144 was used in this example.

The polyimide nanofiber web has properties of a mass per area of 12.7 g/m², a non-contact thickness of 44.3 μm, a measured ATEQ airflow of 75.5 L/hr at 12 mbar and 2.99 cm², and a bubble point pressure of 5.6 psi (0.39 bar).

### Polyimide Membrane (PI2)

A polyimide electrospun membrane available from W.L. Gore & Associates with the part number GCM145 was used in this example.

The polyimide nanofiber web has properties of a mass per area of 11.1 g/m², a non-contact thickness of 57 μm, a measured ATEQ airflow of 201 L/hr at 12 mbar and 2.99 cm² and a bubble point pressure of 1.2 psi (0.08 bar).

### Polyimide Membrane (PI3)

A polyimide electrospun membrane available from W.L. Gore & Associates with the part number GCM146 was used in this example.

The polyimide nanofiber web has properties of a mass per area of 6.6 g/m², a non-contact thickness of 51.8 μm, a measured ATEQ airflow of 456 L/hr at 12 mbar and 2.99 cm² and a bubble point pressure of 3.9 psi (0.27 bar).

### Polypropylene Membrane:

A polypropylene membrane with the part number Celgard 2500 was purchased from Celgard LLC.

The resulting polypropylene membrane has properties of a mass per area of 11.2 g/m², a non-contact thickness of 25 μm, a measured ATEQ airflow of 0.85 L/hr at 12 mbar and 2.99 cm² and a bubble point pressure of 158 psi (10.89 bar).

### Polyamide Membrane (PA1):

An electrospun polyamide 6 membrane used in this example was made according to U.S. Pat. No. 9,101,860B2.

The resulting polyamide nanofiber web has properties of a mass per area of 3.0 g/m², a non-contact thickness of 27 μm, a measured ATEQ airflow of 35 L/hr at 12 mbar and 2.99 cm² and a bubble point pressure of 32 psi (2.21 bar).

### Silicone Membrane (SI1):

A silicone system (“A1”) consisting of an “A” and “B” component was purchased from KauPo Plankenhorn e.K. (Carl-Benz-Str. 4 in 78549 Spaichingen, Germany). This mix consists of a high molecular weight copolymer of dimethylsiloxane and methylvinylsiloxane, fumed silica particles, and a platinum cross-linking agent. The article number was CSG-65 (A+B). PMMA having an average molecule weight of 960,000 g/mol was purchased from Sigma Aldrich. To create the polymer/solvent mix the PMMA was mixed with methylethyl ketone (MEK).

After full dissolution (24 h) of the PMMA, the PDMS silicone system was added to the mix until fully solvated (24 h) to form a PDMS spinning solution.

A polymer/solvent mix (2) (acting as a precursor solution) is retained within a syringe and slowly pumped with a constant rate through a needle with a defined inner diameter. At the needle tip (4) the polymer/solvent mix (2) is charged and the difference in charge between the mix (2) at the needle tip (4) and a grounded collector (6) draws the polymer/solvent mix (2) towards the collector (6) where it forms fine nanofibers that build up to form a nanofiber membrane (8). As the mix (2) travels from the needle tip (4) to the collector (6) solvent evaporates from the mix such that a substantially dry nanofiber is deposited on the collector (6).

In the current example, the PDMS spinning solution was spun with a single nozzle electrospinning machine (“Starter Kit”) obtained from Inovenso, in which high voltage was applied to direct the jet towards the other electrode at high speed where a collector is used to collect the fibers which are formed due to the forces on the electrospinning solution. The spun mat was heat treated to obtain a cured nonwoven material that contains nanofibers. In particular, an electrospun nanofiber membrane was made using a single needle electrospinning device and a static aluminum drum (80 mm diameter) collector with feeding the polymer/solvent system through a small diameter needle that is connected to a high voltage generator. The strong electric field is stretching the polymer/solvent system to form a fine nanofiber.

The created nanofibers were collected on a “substrate” that was wrapped around the aluminum drum, so that after creation of a nanofiber nonwoven membrane the “removable processing carrier” can be peeled off the nanofiber nonwoven membrane to obtain a “standalone nanofiber membrane”. Those “removable processing carrier” need to avoid an unwanted strong adhesion of the nanofibers so that they are fully removable.

Example SI1 was created using a 0.51 mm inner diameter needle, a distance from the needle tip to collector of 100 mm, 14 kV positive voltage on needle and a grounded metal collector electrode, an antistatic PTFE/glassfiber woven substrate and 120 minutes spinning time. The environmental conditions were approximately 22° C. and 50% humidity.

### Curing:

The nanofiber membrane on the substrate was cured in an oven at a temperature of 155° C. for 15 min to obtain a cured silicone rubber nanofiber membrane.

The resulting silicone rubber nanofiber web has properties of a mass per area of 27.5 g/m², a non-contact thickness of 36 μm, a measured ATEQ airflow of 33.6 L/hr at 12 mbar and 2.99 cm² and a bubble point pressure of 6 psi (0.41 bar).

### Coatings:

Dowsil 1-4105: a heat-cured silicone-based conformal coating from Dow Inc. with a lower viscosity of 450 cP and durometer value of 64.

Dowsil 1-2577: a moisture-cured silicone-based conformal coating from Dow Inc. with a higher viscosity of 950 cP and durometer value of 80.

FibraLAST TLF-506C: (a coating from AGC Chemicals Americas, Inc. comprising a non-fluorinated polymer emulsion).

UNIDYNE XP-8001: (an acrylic-based coating from Daikin Industries, Ltd.).

### Example 6

A vent assembly comprised a first membrane, a second membrane and a third membrane. The first membrane comprised the polyimide membrane (PI1) above was coated with a coating formulated with 9 wt % Dowsil 1-4105 (a silicone-based coating from Dow Inc.) in Methyl Ethyl Ketone (MEK) and applied to the surface using a Mayer rod. The membrane is restrained in both axes and dried in an oven at 150° C. for 3.5 minutes. The second membrane and the third membrane comprised the ePE membrane ePE2 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 7 (Comparative)

A comparative vent assembly comprises a first membrane, and a second membrane. Both membranes comprised the ePE membrane ePE2 as described above. An acrylic adhesive layer (Part number 5603R from Nitto Denko Corporation) is provided between the first membrane and the second membrane. An air gap of 30 μm is defined between the first membrane and the second membrane.

### Example 8 (Comparative)

A comparative vent assembly comprises a first membrane, a second membrane and a third membrane. Each membrane comprised the ePE membrane ePE2 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 9 (Comparative)

A comparative vent assembly comprised a single membrane. The single membrane comprised the polyimide membrane (PI1) as described above coated with a coating formulated with 3 wt % Dowsil 1-4105 in Methyl Ethyl Ketone (MEK) and applied to the surface by hand until the membrane is fully saturated. Excess coating is removed and allowed to air dry. The membrane is restrained in both axes and dried in an oven at 120° C. for 3.5 minutes.

### Example 10

A vent assembly comprised a first membrane, a second membrane and a third membrane. The first membrane comprised the expanded polyethylene membrane (ePE1) above coated with a coating formulated with 1.5 wt % Dowsil 1-4105 in Methyl Ethyl Ketone (MEK) and applied to the surface by hand until the membrane is fully saturated. Excess coating is removed and allowed to air dry. The membrane is restrained in both axes and dried in an oven at 120° C. for 5 minutes. The second membrane and the third membrane comprised the ePE membrane ePE2 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 11 (Comparative)

A comparative vent assembly comprises a single membrane comprising the expanded polyethylene membrane (ePE1) above coated with a coating formulated with 1.5 wt % Dowsil 1-4105 in Methyl Ethyl Ketone (MEK) and applied to the surface by hand until the membrane is fully saturated. Excess coating is removed and allowed to air dry. The membrane is restrained in both axes and dried in an oven at 120° C. for 5 minutes.

### Example 12

A vent assembly comprised a first membrane, and a second membrane. The first membrane comprised the polyimide membrane (PI1) above was coated with a coating formulated with 9 wt % Dowsil 1-4105 (a silicone-based coating from Dow Inc.) in Methyl Ethyl Ketone (MEK) and applied to the surface using a Mayer rod. The membrane is restrained in both axes and dried in an oven at 150° C. for 3.5 minutes. The second membrane comprised the ePE membrane ePE2 as described above. An acrylic adhesive layer (Part number 5603R from Nitto Denko Corporation) is provided between the first membrane and the second membrane. An air gap of 30 μm is defined between the first membrane and the second membrane.

### Example 13

A vent assembly comprised a first membrane, a second membrane and a third membrane. The first membrane comprised the expanded polyethylene membrane (ePE1) above coated with a coating formulated with 1.5 wt % Dowsil 1-4105 in Methyl Ethyl Ketone (MEK) and applied to the surface by hand until the membrane is fully saturated. Excess coating is removed and allowed to air dry. The membrane is restrained in both axes and dried in an oven at 120° C. for 5 minutes. The second membrane and the third membrane comprised the PP membrane PP1 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 14

A vent assembly comprised a first membrane, a second membrane and a third membrane. The first membrane comprised the polyimide membrane (PI1) above was coated with a coating formulated with 9 wt % Dowsil 1-4105 (a silicone-based coating from Dow Inc.) in Methyl Ethyl Ketone (MEK) and applied to the surface using a Mayer rod. The membrane is restrained in both axes and dried in an oven at 150° C. for 3.5 minutes. The second membrane and the third membrane comprised the PP membrane PP1 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 15 (Comparative)

A comparative vent assembly comprises a first membrane, and a second membrane. Both membranes comprised the PP membrane PP1 as described above. An acrylic adhesive layer (Part number 5603R from Nitto Denko Corporation) is provided between the first membrane and the second membrane. An air gap of 30 μm is defined between the first membrane and the second membrane.

### Example 16 (Comparative)

A comparative vent assembly comprises a first membrane, a second membrane and a third membrane. Each membrane comprised the PP membrane PP1 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 17

A vent assembly comprises a first membrane, a second membrane and a third membrane. The first membranes comprised the SI membrane SI1 as described above. The second membrane and the third membrane comprised the ePE membrane ePE2 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 18 (Comparative)

A comparative vent assembly comprises a first membrane, a second membrane, a third membrane and a fourth membrane. Each membrane comprised the ePE membrane ePE2 as described above. An acrylic adhesive layer (Part number 5603R from Nitto Denko Corporation) is provided between the first membrane and the second membrane, a further acrylic adhesive layer (Part number 5603R from Nitto Denko Corporation) is provided between the second membrane and the third membrane and further acrylic adhesive layer (Part number 5603R from Nitto Denko Corporation) is provided between the third membrane and the fourth membrane. An air gap of 30 μm is defined between the first membrane and the second membrane, between the second membrane and the third membrane, and between the third membrane and the fourth membrane.

### Example 19

A vent assembly comprises a first membrane, a second membrane, a third membrane and a fourth membrane. The first membrane comprised the polyimide membrane (PI1) above was coated with a coating formulated with 9 wt % Dowsil 1-4105 (a silicone-based coating from Dow Inc.) in Methyl Ethyl Ketone (MEK) and applied to the surface using a Mayer rod. The membrane is restrained in both axes and dried in an oven at 150° C. for 3.5 minutes. The second membrane, third membrane, and fourth membrane comprised the ePE membrane ePE2 as described above. An acrylic adhesive layer (Part number 5603R from Nitto Denko Corporation) is provided between the first membrane and the second membrane, a further acrylic adhesive layer (Part number 5603R from Nitto Denko Corporation) is provided between the second membrane and the third membrane and further acrylic adhesive layer (Part number 5603R from Nitto Denko Corporation) is provided between the third membrane and the fourth membrane. An air gap of 30 μm is defined between the first membrane and the second membrane, between the second membrane and the third membrane, and between the third membrane and the fourth membrane.

### Example 20

A vent assembly comprised a first membrane, a second membrane and a third membrane. The first membrane and second membrane comprised the polyimide membrane (PI1) above was coated with a coating formulated with 9 wt % Dowsil 1-4105 (a silicone-based coating from Dow Inc.) in Methyl Ethyl Ketone (MEK) and applied to the surface using a Mayer rod. The membrane is restrained in both axes and dried in an oven at 150° C. for 3.5 minutes. The third membrane comprised the ePE membrane ePE2 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 21

A vent assembly comprised a first membrane, a second membrane and a third membrane. The first membrane comprised the polyamide membrane (PA1) above was coated with a coating formulated with 3 wt % Dowsil 1-2577 (a silicone-based coating from Dow Inc.) in Methyl Ethyl Ketone (MEK) and applied to the surface by hand until the membrane is fully saturated. Excess coating is removed and allowed to air dry. The membrane is restrained in both axes and dried in an oven at 125° C. for 3.5 minutes. The second membrane and the third membrane comprised the ePE membrane ePE2 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 22

A vent assembly comprised a first membrane, a second membrane and a third membrane. The first membrane comprised the polyimide membrane (PI2) above was coated with a coating formulated with 70 wt % UNIDYNE XP-8001 (an acrylic-based coating commercially available from Daikin Industries, Ltd.) in Isopropyl Alcohol (IPA) and applied to the surface using a Mayer rod. The membrane is restrained in both axes and dried in an oven at 120° C. for 3.5 minutes. The second membrane and the third membrane comprised the ePE membrane ePE3 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

### Example 23

A vent assembly comprised a first membrane, a second membrane and a third membrane. The first membrane comprised the polyimide membrane (PI3) above coated with a coating of 100 wt % FibraLAST TLF-506C (a coating available from AGC Chemicals Americas, Inc) and applied to the surface using a Mayer rod. The membrane is restrained in both axes and dried in an oven at 180° C. for 10.15 minutes. The second membrane and the third membrane comprised the ePE membrane ePE3 as described above. An acrylic adhesive layer (Part number 5603R from Nitto Denko Corporation) is provided between the first membrane and the second membrane and a further acrylic adhesive layer (Part number 5603R from Nitto Denko Corporation) is provided between the second membrane and the third membrane. An air gap of 30 μm is defined between the first membrane and the second membrane and between the second membrane and the third membrane.

The iWEP and Airflow of each example vent assembly were measured using the test methods provided above with the first membrane as defined in Table 1 below being the membrane in the membrane stacks of the vent assemblies facing the challenge (either water or air). The results of these tests are shown in Table 1 below.

TABLE 1
Example vent assemblies and measured properties of those vent assemblies.

| | | | | | iWEP | | Airflow | |
|---|---|---|---|---|---|---|---|---|
| | | | | | post | | post | Airflow |
| | 1^{st} | 2^{nd} | 3^{rd} | 4^{th} | soap, | Airflow, | soap, | Loss, |
| # | Membrane | Membrane | Membrane | Membrane | psi | mL/min | mL/min | % |
| 6 | Silicone | ePE2 | ePE2 | — | 81.4 | 0.1 | 0.07 | −31.6 |
| | coated PI1 | | | | | | | |
| c7 | ePE2 | ePE2 | — | — | 64.5 | 0.08 | 0.01 | −83.8 |
| c8 | ePE2 | ePE2 | ePE2 | — | 90.0 | 0.06 | 0.01 | −82.9 |
| c9 | Silicone | — | — | — | 0.4 | 2.61 | 1.26 | −51.0 |
| | coated PI1 | | | | | | | |
| 10 | Silicone | ePE2 | ePE2 | — | 90.0 | 0.06 | 0.04 | −32.7 |
| | coated | | | | | | | |
| | ePE1 | | | | | | | |
| c11 | Silicone | — | — | — | 0.1 | 2.49 | 1.2 | −51.7 |
| | coated | | | | | | | |
| | ePE1 | | | | | | | |
| 12 | Silicone | ePE2 | — | — | 54.7 | 0.163 | 0.083 | −44.9 |
| | coated PI1 | | | | | | | |
| 13 | Silicone | PP1 | PP1 | — | 90.0 | 0.022 | 0.020 | −10.3 |
| | coated | | | | | | | |
| | ePE1 | | | | | | | |
| 14 | Silicone | PP1 | PP1 | — | 90.0 | 0.023 | 0.017 | −25.5 |
| | coated PI1 | | | | | | | |
| c15 | PP1 | PP1 | — | — | 90.0 | 0.024 | 0.004 | −84.4 |
| c16 | PP1 | PP1 | PP1 | — | 90.0 | 0.017 | 0.008 | −58.2 |
| 17 | SI1 | ePE2 | ePE2 | — | 90.0 | 0.064 | 0.060 | −5.1 |
| c18 | ePE2 | ePE2 | ePE2 | ePE2 | 90.0 | 0.034 | 0.006 | −83.2 |
| 19 | Silicone | ePE2 | ePE2 | ePE2 | 90.0 | 0.042 | 0.044 | 4.1 |
| | coated PI1 | | | | | | | |
| 20 | Silicone | Silicone | ePE2 | — | 90.0 | 0.121 | 0.115 | −4.1 |
| | coated PI1 | coated PI1 | | | | | | |
| 21 | Silicone | ePE2 | ePE2 | — | 86.8 | 0.062 | 0.050 | −19.6 |
| | coated | | | | | | | |
| | PA1 | | | | | | | |
| 22 | acrylic | ePE3 | ePE3 | — | 90.0 | 0.089 | 0.075 | −15.7 |
| | coated PI2 | | | | | | | |
| 23 | Coated | ePE3 | ePE3 | — | 90.0 | 0.099 | 0.097 | −2.0 |
| | PI3 | | | | | | | |

The IPA rating for each membrane in each vent assembly is provided in Table 2 below.

TABLE 2
IPA rating of each membrane in the Example vent assemblies

| | 1^{st} | 2^{nd} | 3^{rd} | 4^{th} |
|---|---|---|---|---|
| | Membrane | Membrane | Membrane | Membrane |
| Example | IPA rating | IPA rating | IPA rating | IPA rating |
| 6 | 35 | 10 | 10 | — |
| c7 | 10 | 10 | — | — |
| c8 | 10 | 10 | 10 | — |
| c9 | 35 | — | — | — |
| 10 | 30 | 10 | 10 | — |
| c11 | 30 | — | — | — |
| 12 | 35 | 10 | — | — |
| 13 | 30 | 20 | 20 | — |
| 14 | 35 | 20 | 20 | — |
| c15 | 20 | 20 | — | — |
| c16 | 20 | 20 | 20 | — |
| 17 | 30 | 10 | 10 | — |
| c18 | 10 | 10 | 10 | 10 |
| 19 | 35 | 10 | 10 | 10 |
| 20 | 35 | 35 | 10 | — |
| 21 | 30 | 10 | 10 | — |
| 22 | 50 | 10 | 10 | — |
| 23 | 50 | 10 | 10 | — |

Examples 6 and 10 above show that reduction in airflow after the immersion in a surfactant solution (soap challenge) is significantly reduced when compared to comparative Examples 7 and 8, for example.

Comparative examples 9 and 11 show that the individual coated membranes (either Silicone coated ePE or Silicone coated PI1 membranes) have low performance in the WEP after the soap challenge compared to Examples 6 and 10 show significantly better performance.

Accordingly, the provision of a coating on at least the first membrane that results in a significant increase in the IPA rating of the first membrane provides significant improvements in performance.

While there has been hereinbefore described approved embodiments of the present invention, it will be readily apparent that many and various changes and modifications in form, design, structure and arrangement of parts may be made for other embodiments without departing from the invention and it will be understood that all such changes and modifications are contemplated as embodiments as a part of the present invention as defined in the appended claims.

1. A vent assembly comprising a membrane stack, the membrane stack comprising a plurality of membranes and an air gap between adjacent membranes in the plurality of membranes, wherein each membrane in the plurality of membranes comprise a non-fluoropolymer and substantially occlude each other in the membrane stack, wherein a first membrane in the plurality of membranes has an isopropyl alcohol (IPA) rating of at least 30% IPA/water and at least one membrane in the plurality of membranes has a bubble point of at least 2 bar as measured using the test method provided herein.

2. The vent assembly of claim 1, wherein the first membrane is the first membrane in the membrane stack.

3. The vent assembly of claim 1, wherein the first membrane comprises a coating and the coating reduces the surface energy of at least an outward facing surface of the first membrane.

4. The vent assembly of claim 3, wherein the coating comprises silicone, poly(methyl methacrylate) (PMMA), or an acrylate copolymer.

5. The vent assembly of claim 1, wherein the first membrane comprises a hydrophobic non-fluoropolymer.

6. The vent assembly of claim 5, wherein the first membrane comprises a polysiloxane.

7. The vent assembly of claim 1, wherein the plurality of membranes comprises a first membrane, a second membrane and a third membrane, wherein the second membrane is positioned between the first membrane and the third membrane, the membrane stack comprising a first air gap positioned between the first membrane and the second membrane, and a second air gap positioned between the second membrane and the third membrane.

8. The vent assembly of claim 7, wherein the first membrane has a first surface adjacent to the first air gap and a second surface opposed to the first surface and at least the second surface has an IPA rating of at least 30% IPA/water.

9. The vent assembly of claim 1, wherein the non-fluoropolymer comprises polyethylene, polypropylene, polyimide, polyamide, or polyurethane.

10. The vent assembly of claim 9, wherein the first membrane comprises polyethylene or polyimide.

11. The vent assembly of claim 7, wherein the second membrane comprises polyethylene or polyimide.

12. The vent assembly of claim 7, wherein the third membrane comprises polyethylene.

13. The vent assembly of claim 7, wherein the second membrane has an IPA rating of at least 30% IPA/water.

14. The vent assembly of claim 13, wherein the second membrane comprises a coating.

15. The vent assembly of claim 14, wherein the coating comprises silicone, poly(methyl methacrylate) (PMMA), or an acrylate copolymer.

16. The vent assembly of claim 7, wherein the third membrane does not comprise a coating.

17. The vent assembly of claim 1, wherein the vent assembly has a failure pressure of at least 70 psi as measured in a water entry pressure (WEP) test using the test methods provided herein.

18. The vent assembly of claim 1, wherein the vent assembly has a reduction in airflow of less than 80% after a contamination test as measured using the test method described herein.

19. The vent assembly of claim 1, wherein the membrane stack comprises an adhesive layer between adjacent membranes in the membrane stack.

20. The vent assembly of claim 1, wherein the or each adhesive layer define an adhesive layer aperture and each membrane in the plurality of membranes occlude the adhesive layer aperture.

21. The vent assembly of claim 20, wherein the or each adhesive layer comprise a heat activated film (HAF) or a pressure sensitive adhesive (PSA).

22. The vent assembly of claim 1, wherein the at least one membrane in the plurality of membranes has a bubble point of from 2 bar to 15 bar.

23. The vent assembly of claim 1, wherein the at least one membrane in the plurality of membranes has a bubble point of from 6 bar to 11 bar.

24. The vent assembly of claim 1, wherein the air gap between adjacent membranes is at least 20 μm.

25. The vent assembly of claim 1, wherein the air gap between adjacent membranes is from 20 μm to 100 μm.

26. A device comprising a housing defining an aperture and a vent assembly according to claim 1 positioned over the aperture, the housing having an interior and an exterior, wherein the first membrane of the membrane stack of the vent assembly faces the exterior of the housing.

27. The device of claim 26, wherein the device is an electronic device.

28. The device of claim 27, wherein the vent assembly is positioned adjacent to an acoustic transducer.

29. The device of claim 28, wherein the acoustic transducer is a speaker or a microphone.
